(19) United States
(12) Patent Application Publication
(10) Pub. No.: US 2007/0084406 A1
(43) Pub. Date: Apr. 19, 2007

(54) Reaction chamber with opposing pockets for gas injection and exhaust

(76) Inventors: Joseph Yudovsky, Campbell (CA); Robert C. Cook, Pleasanton, CA (US); Yeong K. Kim, Pleasanton, CA (US); Alexander Tam, Union City, CA (US); Maitreyee Mahajani, Saratoga, CA (US); Adam A. Brailove, Gloucester, MA (US); Steve G. Ghanayem, Los Altos, CA (US)

Correspondence Address: PATTERSON & SHERIDAN, LLP, 3040 POST OAK BOULEVARD, SUITE 1500, HOUSTON, TX, 77056, US

(21) Appl. No.: 11/249,555

(22) Filed: Oct. 13, 2005

(51) Int. Cl. C23F 1/00; C23C 16/00

(52) U.S. Cl. 118/724; 118/719; 156/345.31; 156/345.27

(57) ABSTRACT

The present invention generally provides a batch processing chamber having a quartz chamber, at least one heater block, an inject assembly coupled to one side of the quartz chamber, and an exhaust assembly coupled to an opposite side of the quartz chamber. In one embodiment, the inject assembly is independently temperature controlled. In another embodiment, at least one temperature sensor is disposed outside the quartz chamber.

### BACKGROUND OF THE INVENTION

1. Field of the Invention

Embodiments of the present invention generally relate to a batch processing chamber.

2.Description of the Related Art

The effectiveness of a substrate fabrication process is often measured by two related and important factors, which are device yield and the cost of ownership (COO). These factors are important since they directly affect the cost to produce an electronic device and thus a device manufacturer's competitiveness in the market place. The COO, while affected by a number of factors, is greatly affected by the number of substrates processed per hour and cost of processing materials. Batch processing has been introduced to reduce COO and is very effective. A batch processing chamber is generally complicatedly equipped with, for example, a heating system, a gas delivery system, an exhaust system, and a pumping system.

FIGS. 1 and 2 illustrate a known batch processing chamber. Referring to FIG. 1, which illustrates a batch processing chamber 100 in a processing condition. In this condition, a batch of substrates 102 supported by a substrate boat 101 may be processed in a process volume 103 defined by a top 104, sidewalls 105, and a bottom 106. An aperture 122 is formed in the bottom 106 providing a means for the substrate boat to be inserted into the process volume 103 or removed from the process volume 103. A seal plate 107 is provided to seal off the aperture 122 during a process.

Heating structures 110 are mounted on exterior surfaces of each of the sidewalls 105. Each of the heating structure 110 contains a plurality of halogen lamps 119 which are used to provide energy to the substrates 102 in the process volume 103 of the batch processing chamber 100 through a quartz window 109 mounted on the sidewalls 105. A thermal shield plate 108 mounted on an inside surface of the sidewalls 105 are added to the process volume 103 to diffuse the energy emitted from the heating structures 110 to allow a uniform distribution of heat energy to be provided to the substrates 102. A multiple zone heating structure 111 containing an array of halogen lamps 121 is amounted to the top 104. The halogen lamps 121 radiate energy towards the substrates 102 in the substrate boat 101 through a quartz window 113 and a thermal shield plate 112.

The sidewalls 105 and the top 104 are generally temperature controlled by milled channels 116 (shown in FIG. 2) to avoid unwanted deposition and for safety reasons as well. When the quartz windows 109 are hot and the process volume 103 is under vacuum, undue stress may cause an implosion if the quartz windows 109 come in direct contact with the temperature controlled sidewalls 105. Therefore, O-ring type gaskets 124 (constructed of a suitable material such as, for instance, viton, silicon rubber, or cal-rez graphite fiber) and strip gaskets 123 of a similar suitable material are provided between the quartz windows 109 and sidewalls 105 to ensure that the quartz windows 109 do not come in direct contact with the sidewalls 105 to prevent implosion. The thermal shield plates 108 are mounted on the sidewalls 105 by insulating strips 125 and retaining clamps 126. The thermal shield plates 108 and the insulating strips 125 are made of a suitable high temperature materials such as, for instance, graphite or silicon carbide. The retaining clamps 126 are made from suitable high temperature material such as titanium.

The milled channels 116 formed in the sidewalls 105 may be temperature controlled by use of a heat exchanging fluid that is continually flowing through the milled channels 116. The heat exchanging fluid may be, for example, a perfluoropolyether (e.g., Galden® fluid) that is heated to a temperature between about 30° C. and about 300° C. The heat exchanging fluid may also be chilled water delivered at a desired temperature between about 15° C. to 95° C. The heat exchanging fluid may also be a temperature controlled gas, such as, argon or nitrogen.

Details of the heating structures 110 and multizone heat structure 111 are further described in patent application Ser. No. 6,352,593, entitled “Mini-batch Process Chamber” filed Aug. 11, 1997, and U.S. patent application Ser. No. 10/216,079, entitled “High Rate Deposition At Low Pressure In A Small Batch Reactor” filed Aug. 9, 2002 which are incorporated herein by reference.

Referring now to FIG. 2, process gases to be used in depositing layers on substrates 102 are provided through a gas injection assembly 114. The injection assembly 114 is vacuum sealed to the sidewalls 105 via an O-ring. An exhaust assembly 115 is disposed on an opposite side of the injection assembly 114. In this configuration, the injection assembly and the exhaust assembly are not directly temperature controlled and are prone to condensation and decomposition which introduce particle contamination to the batch processing chamber.

Several aspects of the known batch processing chamber are in need of improvement. First, since substrates are circular, a process volume in a boxed chamber is not utilized efficiently. Therefore, processing gases are wasted and residence time ( the average time it takes a molecule of gas to travel from the point of injection to its being exhausted on the opposite side of the chamber) of the reactive gases is elongated. Second, the inject assembly and the exhaust assembly are not temperature controlled, therefore, are susceptible to condensation and decomposition caused by too high or too low a temperature. Third, the heating system is complex and difficult to repair and clean. Fourth, many pressure insulating seals are used which increases the system complexity and makes it vulnerable to leaks. Therefore, there is a need for a system, a method and an apparatus that provide an improved and simplified batch processing chamber.

### SUMMARY OF THE INVENTION

The present invention generally provides a batch processing chamber having a quartz chamber, at least one heater block, an inject assembly coupled to one side of the quartz chamber and an exhaust assembly coupled to an opposite side of the quartz chamber.

One embodiment of the present invention provides a batch processing chamber having a quartz chamber, at least one heater block, an inject assembly coupled to one side of the quartz chamber and an exhaust assembly coupled to an opposite side of the quartz chamber. The inject assembly comprises a heater and cooling channels such that the inject assembly is temperature controlled.

Another embodiment of the present invention provides a batch processing chamber having a quartz chamber, at least one heater block, an inject assembly coupled to one side of the quartz chamber, an exhaust assembly coupled to an opposite side of the quartz chamber, and an outer chamber which encloses the quartz chamber and the at least one heater block.

Another embodiment of the present invention provides a batch processing chamber having a quartz chamber, at least one heater block, an inject assembly coupled to one side of the quartz chamber, an exhaust assembly coupled to an opposite side of the quartz chamber, and at least one temperature sensor disposed outside the quartz chamber.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 (prior art) illustrates a sectional side view of a known batch processing chamber.

FIG. 2 (prior art) illustrates a sectional top view of the known batch processing chamber shown in FIG. 1.

FIG. 3 illustrates an exploded view of an exemplary batch processing chamber of the present invention.

FIG. 4 illustrates a sectional side view of an exemplary batch processing chamber of the present invention.

FIG. 5 illustrates a sectional top view of the batch processing chamber of FIG. 4.

FIG. 6 illustrates a sectional view of another embodiment of the present invention.

FIG. 7 illustrates a sectional side view of an exemplary batch processing chamber of the present invention.

FIG. 8 illustrates a sectional top view of the batch processing chamber of FIG. 7.

FIG. 9 illustrates a sectional side view of an exemplary batch processing chamber of the present invention.

FIG. 10 illustrates a sectional top view of the batch processing chamber of FIG. 9.

FIG. 11 illustrates a sectional top view of an exemplary batch processing chamber of the present invention.

FIG. 12A illustrates a sectional side view of the batch processing chamber of FIG. 11.

FIG. 12B illustrates a sectional side view of another embodiment of the present invention.

FIG. 13A illustrates a sectional top view of an exemplary batch processing chamber of the present invention.

FIG. 13B is an exploded view an the batch processing chamber of FIG. 13A.

FIG. 14 illustrates a sectional side view of the batch processing chamber of FIG. 13A.

FIG. 15 illustrates a front view of a purge gas supply assembly used in a batch processing chamber.

FIG. 16 illustrates a side view of the purge gas supply assembly of FIG. 15.

FIG. 17 illustrates an embodiment of an inject assembly of a batch processing chamber of the present invention.

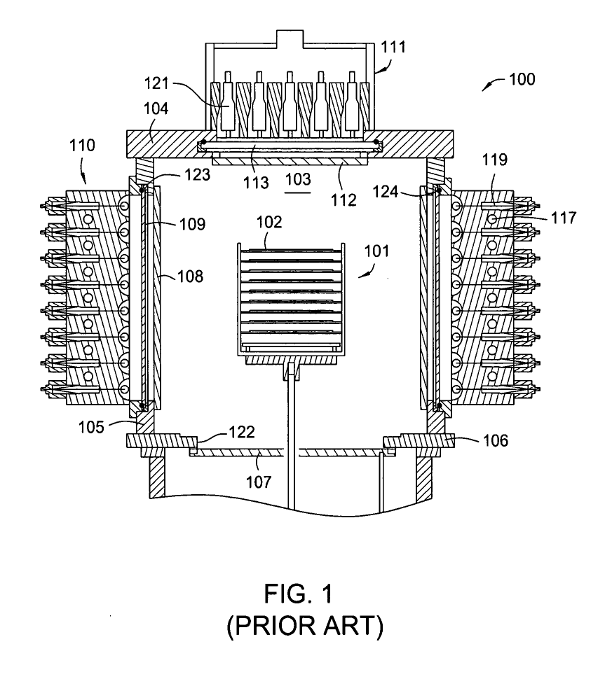

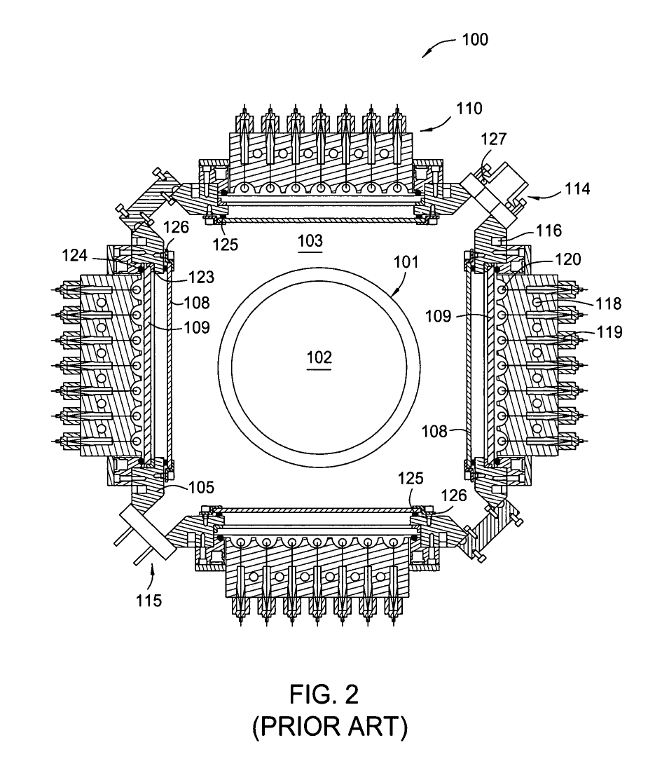

### DETAILED DESCRIPTION

The present invention generally provides an apparatus and a method for processing semiconductor substrates in a batch. In one aspect of the present invention, a batch processing chamber having a quartz chamber with an inject pocket and an exhaust pocket is provided. The invention is illustratively described below in reference to modification of a FlexStar™ system, available from Applied Materials, Inc., Santa Clara, Calif.

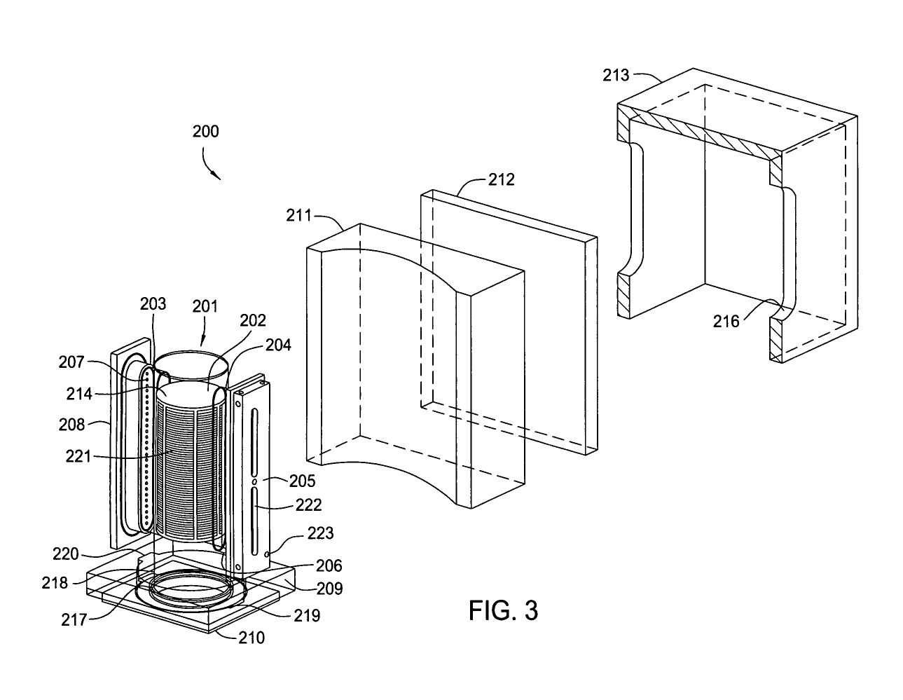

FIG. 3 illustrates an exploded view of an exemplary batch processing chamber of the present invention. A batch processing chamber 200 generally comprises a quartz chamber 201 configured to accommodate a substrate boat 214. The quartz chamber 201 generally comprises a dome type of chamber body 202, an inject pocket 204 formed on one side of the chamber body 202, an exhaust pocket 203 formed on the chamber body 202 on an opposite side of the inject pocket 204, and a flange 217 formed adjacent to an opening 218 of the chamber body 202. The substrate boat 214 is configured to support and transfer a batch of substrates 221 to and from the quartz chamber 201 via the opening 218. The flange 217 may be welded on the chamber body 202 to reduce O-rings used for vacuum sealing. The exhaust pocket 203 and the inject pocket 204 may be welded in place of slots milled on the chamber body 202. In one aspect, the inject pocket 204 and the exhaust pocket 203 are flattened quartz tubing with one end welded on the chamber body 202 and one end open. The inject pocket 204 and the exhaust pocket 203 are configured to house an inject 205 and an exhaust 207 respectively. The quartz chamber 201 is generally made of (fused) quartz which is ideal for a furnace chamber. In one aspect, quartz is an economical material with a combination of high purity and high temperature properties. In another aspect, quartz can tolerate wide temperature gradients and high heat rates.

The quartz chamber 201 is generally supported by a support plate 210 near the opening 218. An O-ring seal 219 is used for vacuum sealing between the quartz chamber 201 and the support plate 210. A chamber stack support 209 having an aperture 220 is disposed on the support plate 210. One or more heater blocks 211 are generally disposed around the chamber body 202 and are configured to provide heat energy to the substrate 221 inside the quartz chamber 201 through the chamber body 202. In one aspect, the one or more heater blocks 211 may have multiple vertical zones. A plurality of quartz liners 212 may be disposed around the one or more heater blocks 211 to prevent heat energy from radiating outwards. An outer chamber 213 is disposed over the quartz chamber 201, the one or more heater blocks 211, and the quartz liners 212 and is rested on the stack support 209, providing vacuum sealing for the heater blocks 211 and the quartz liners 212. Openings 216 may be formed on sides of the outer chamber 213 for the inject 205 and the exhaust 207 to pass through. Thermal insulators 206 and 208 are generally disposed between the inject pocket 204 and the outer chamber 213, and the exhaust pocket 203 and the outer chamber 213 respectively. Since the thermal insulators 206 and 208 and the quartz liners 212 insulate the outer chamber 213 from the heater blocks 211 and the heated quartz chamber 201, the outer chamber 213 may stay “cool” during a heated process. In one aspect, the outer chamber 213 is made of metal, such as aluminum and stainless steel.

In one aspect, the inject 205 and/or the exhaust 207 may be temperature controlled independently from the quartz chamber 201. For example, as illustrated in FIG. 3, heater slots 222 and cooling channel 223 are provided in the inject 205 for heating and cooling the inject 205 independently.

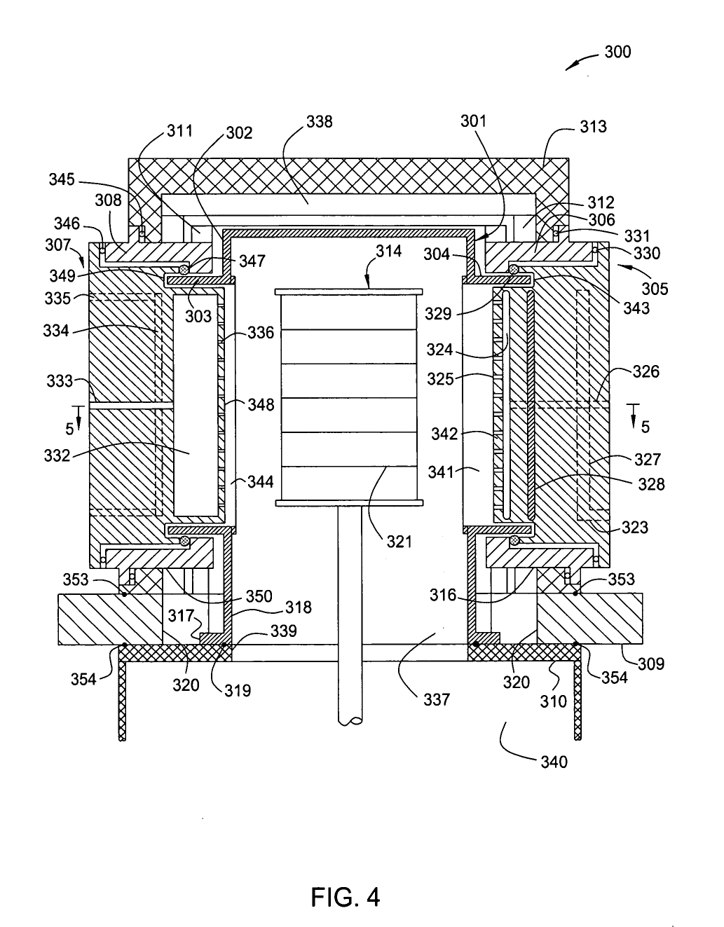

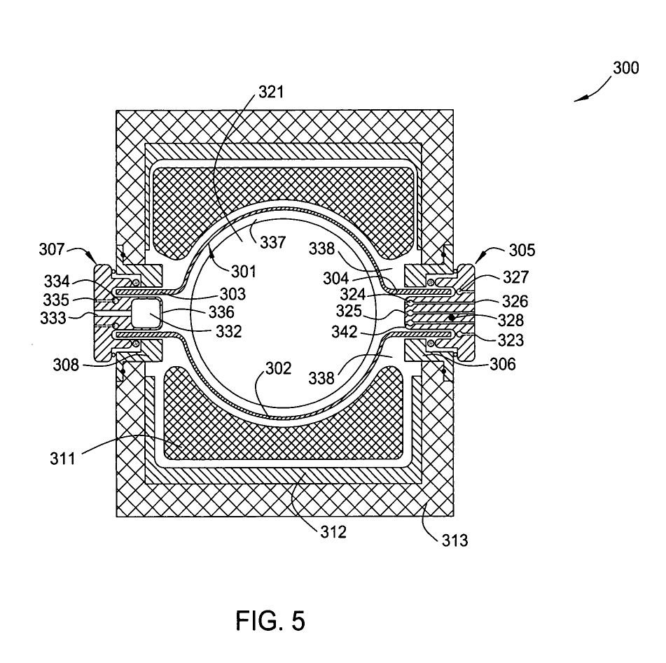

FIGS. 4 and 5 illustrate one embodiment of a batch processing chamber having a quartz chamber, and temperature controlled inject and exhaust. FIG. 4 is a sectional side view of a batch processing chamber 300 and FIG. 5 is a sectional view of the batch processing chamber 300 along direction 5-5 shown in FIG. 4. The batch processing chamber 300 generally comprises a quartz chamber 301 defining a process volume 337 configured to accommodate a batch of substrates 321 stacked in a substrate boat 314. One or more heater blocks 311 are generally arranged around the quartz chamber 301 configured to heat the substrates 321 inside the process volume 337. An outer chamber 313 is generally disposed over the quartz chamber 301 and the one or more heater blocks 311. One or more thermal insulators 312 is generally disposed between the outer chamber 313 and the one or more heater blocks 311 configured to keep the outer chamber 313 staying cool. The quartz chamber 301 is supported by a quartz support plate 310. The outer chamber 313 is connected to a chamber stack support 309 which is supported by the quartz support plate 310.

The quartz chamber 301 generally comprises a chamber body 302 having an opening 318 on a bottom, an inject pocket 304 formed on one side of the chamber body 302, an exhaust pocket 303 formed on the chamber body 302 on an opposite side of the inject pocket 304, and a flange 317 formed adjacent to the opening 318 of the chamber body 302. The chamber body 302 having a cylindrical shape similar to that of the substrate boat 314 reduces the process volume 337 compared to a boxed processing chamber of prior art. A reduced process volume during batch processing is desirable because it not only reduces the amount of processing gas needed per batch but also shortens residence time. The exhaust pocket 303 and the inject pocket 304 may be welded in place of slots milled on the chamber body 302. In one aspect, the inject pocket 204 and the exhaust pocket 203 are flattened quartz tubing with one end welded on the chamber body 202 and one end open. The inject pocket 304 and the exhaust pocket 303 are configured to house a temperature controlled inject assembly 305 and a temperature controlled exhaust assembly 307 respectively. The flange 317 may be welded on the chamber body 302. The flange 317 is generally positioned on the quartz support plate 310 such that the opening 318 is in line with an aperture 339 formed on the quartz support plate 310. The flange 317 is generally in intimate contact with the quartz support plate 310. An O-ring seal 319 may be disposed between the flange 317 and the quartz support plate 310 to seal the process volume 337 from an outer volume 338 defined by the outer chamber 313, the chamber stack support 309, the quartz support plate 310 and the quartz chamber 301. The quartz support plate 310 is further connected to a load lock 340 where the substrate boat 314 may be loaded and unloaded. The substrate boat 314 may be vertically translated between the process volume 337 and the load lock 340 via the aperture 339 and the opening 318.

Examples of substrate boats used in batch processing is further described in U.S. patent application entitled “Batch Deposition Tool and Compressed Boat”, attorney docket number APPM/009848/FEP/LPCVD/AG, which is incorporated herein by reference. Examples of method and apparatus for loading and unloading a substrate boat used in batch processing is further described in U.S. patent application entitled “Batch Wafer Handling System”, attorney docket number APPM/010010/FEP/LPCVD/AG, which is incorporated herein by reference.

Referring to FIG. 5, the heater blocks 311 generally wrap around an outer periphery of the quartz chamber 301 except near the inject pocket 304 and the exhaust pocket 303. The substrates 321 are heated to an appropriate temperature by the heater blocks 311 through the quart chamber 301. To achieve uniform and desirable process results on all areas of the substrates 321 requires that every point on all of the substrates 321 to be evenly heated. Some processes require that the every point on all of the substrates 321 in a batch attain the same set point temperature plus or minus 1 degree Celsius. Configurations of the batch processing chamber 300 improve temperature uniformity in batch processing. In one aspect, edges of the substrates 321 are evenly distanced from the quartz chamber 301 because both the substrates 321 and the chamber body 302 are circular. In another aspect, the heater blocks 311 have multiple controllable zones so that temperature variations between regions may be adjusted. In one embodiment, the heater blocks 311 are made of resistive heaters arranged in multiple vertical zones. In one aspect, the heater blocks 311 are ceramic resistive heaters. In one embodiment, the heater blocks 311 are removable via openings formed on the outer chamber 313. Examples of removable heaters used in batch processing is further described in U.S. patent application entitled “Removable Heater”, attorney docket number APPM/009826/FEP/LPCVD/AG, which is incorporated herein by reference.

Referring to FIG. 4, the inject pocket 304 may be welded on a side of the chamber body 302 defining an inject volume 341 in communication with the process volume 337. The inject volume 341 generally covers an entire height of the substrate boat 314 when the substrate boat 314 is in a process position such that the inject assembly 305 disposed in the inject pocket 304 may provide a horizontal flow of processing gases to every substrate 321 in the substrate boat 314. In one aspect, the inject assembly 305 having an intruding center portion 342 configured to fit in the inject volume 341. A recess 343 configured to hold walls of the inject pocket 304 is generally formed around the center portion 342. The walls of the inject pocket 304 is generally wrapped around by the inject assembly 305. A thermal insulator 306 is generally disposed between the inject assembly 305 and an inject opening 316 formed on the outer chamber 313. In one aspect, the outer volume 338, which includes inside of the outer chamber 313 and outside of the quartz chamber 301, is kept in a vacuum state. Since the process volume 337 and the inject volume 341 are usually kept in a vacuum state during process, keeping the outer volume 338 vacuumed can reduce pressure generated stress on the quartz chamber 301. An O-ring seal 331 may be disposed between the outer chamber 313 and the thermal insulator 306 to provide a vacuum seal to the outer volume 338. An O-ring seal 330 may be disposed between the inject assembly 305 and the thermal insulator 306 to provide a vacuum seal for the inject volume 341. A barrier seal 329 is disposed outside the inject pocket 304 preventing processing chemicals in the process volume 337 and the inject volume 341 from escaping to the outer volume 338. In another aspect, the outer volume 338 may be under atmospheric pressure.

The thermal insulator 306 serves two purposes. On the one hand, the thermal insulator 306 insulates the quartz chamber 301 and the inject assembly 305 from the outer chamber 313 to avoid damages caused by thermal stress due to direct contact between the heated quartz chamber 301/the inject assembly 305 and the “cool” outer chamber 313. On the other hand, the thermal insulator 306 shields the inject pockets 304 and the inject assembly 305 from the heater blocks 311 so that the inject assembly 305 may be temperature controlled independently from the quartz chamber 301.

Referring to FIG. 5, three inlet channels 326 are milled horizontally across the inject assembly 305. Each of the three inlet channels 326 is configured to supply the process volume 337 with a processing gas independently. Each inlet channel 326 is connected to a vertical channel 324 formed near an end of the center portion 342. The vertical channels 324 are further connected to a plurality of evenly distributed horizontal holes 325 and form a vertical shower head on the center portion 342 of the inject assembly 305 (shown in FIG. 4). During process, a processing gas first flows from one of the inlet channels 326 to the corresponding vertical channel 324. The processing gas then flows into the process volume 337 horizontally through the plurality of horizontal holes 325. In one aspect, the inlet channel 326 is connected to the corresponding vertical channel 324 near a center point of the vertical channel 324 such that an average length of the path of the processing gas is short. In another aspect, the horizontal holes 325 may increase in size as they are disposed away from the inlet channel 326 such that gas flows in all the horizontal holes 325 are close to equal. In one embodiment, more or less inlet channels 326 may be formed in the inject assembly 305 depending on requirements of the process performed in the batch processing chamber 300. In another embodiment, since the inject assembly 305 may be installed and removed from outside of the outer chamber 313, the inject assembly 305 may be interchangeable to satisfy different needs.

It is important to control the temperature of various components in a batch processing chamber especially when a deposition process is to be performed in the batch processing chamber. If the temperature of the inject assembly is too low, the gas injected may condense and remain on the surface of the inject assembly, which can generate particles and affect the chamber process. If the temperature of the inject assembly is high enough to evoke gas phase decomposition and/or surface decomposition which may “clog” paths in the inject assembly. Ideally, an inject assembly of a batch processing chamber is heated to a temperature lower than a decomposition temperature of a gas being injected and higher than a condensation temperature of the gas. The temperature ideal for the inject assembly is generally different than the processing temperature in the process volume. For example, during an atomic layer deposition, substrates being processed may be heated up to 600 degrees Celsius, while the ideal temperature for the inject assembly is about 80 degrees Celsius. Therefore, it is necessary to control the temperature of the inject assembly independently.

Referring to FIG. 4, one or more heaters 328 are disposed inside the inject assembly 305 adjacent to the inlet channels 326. The one or more heaters 328 are configured to heat the inject assembly 305 to a set temperature and may be made of resistive heater elements, heat exchangers, etc. Cooling channels 327 are formed in the inject assembly 305 outside the one or more heaters 328. In one aspect, the cooling channels 327 provide further control the temperature of the inject assembly 305. In another aspect, the cooling channels 327 keep an outside surface of the inject assembly 305 staying cool. In one embodiment, the cooling channels 327 may comprise two vertical channels that drilled slightly in an angle so that they meet on one end. Horizontal inlet/outlet 323 is connected to each of the cooling channels 327 such that a heat exchanging fluid may continually flow through the cooling channels 327. The heat exchanging fluid may be, for example, a perfluoropolyether (e.g., Galden® fluid) that is heated to a temperature between about 30° C. and about 300° C. The heat exchanging fluid may also be chilled water delivered at a desired temperature between about 15° C. to 95° C. The heat exchanging fluid may also be a temperature controlled gas, such as, argon or nitrogen.

Referring to FIG. 4, the exhaust pocket 303 may be welded on an opposite side of the inject pocket 304 of the chamber body 302. The exhaust pocket 303 defines an exhaust volume 344 in communication with the process volume 337. The exhaust volume 344 generally covers the height of the substrate boat 314 when the substrate boat 314 is in a process position such that the processing gases may exit the process volume 337 evenly through the exhaust assembly 307 disposed in the exhaust pocket 303. In one aspect, the exhaust assembly 307 having an intruding center portion 348 configured to fit in the exhaust volume 344. A recess 349 is formed around the center portion 348 and is configured to hold walls of the exhaust pocket 304. The walls of the exhaust pocket 303 is wrapped around by the exhaust assembly 307. A thermal insulator 308 is disposed between the exhaust assembly 307 and an exhaust opening 350 formed on the outer chamber 313. An O-ring seal 345 is disposed between the outer chamber 313 and the thermal insulator 308 to provide a vacuum seal to the outer volume 338. An O-ring seal 346 is disposed between the exhaust assembly 307 and the thermal insulator 308 to provide a vacuum seal for the exhaust volume 344. A barrier seal 347 is disposed outside the exhaust pocket 303 to prevent processing chemicals in the process volume 337 and the exhaust volume 344 from escaping to the outer volume 338.

The thermal insulator 308 serves two purposes. On the one hand, the thermal insulator 308 insulates the quartz chamber 301 and the exhaust assembly 307 from the outer chamber 313 to avoid damages caused by thermal stress due to direct contact between the heated quartz chamber 301/the exhuast assembly 307 and the “cool” outer chamber 313. On the other hand, the thermal insulator 308 shields the exhaust pockets 303 and the exhaust assembly 307 from the heater blocks 311 so that the exhaust assembly 307 may be temperature controlled independently from the quartz chamber 301.

Referring to FIG. 5, an exhaust port 333 is formed horizontally across the exhaust assembly 307 near a center portion. The exhaust port 333 opens to a vertical compartment 332 formed in the intruding center portion 348. The vertical compartment 332 is further connected to a plurality of horizontal slots 336 which are open to the process volume 337. When the process volume 337 is being pumped out, processing gases first flow from the process volume 337 to the vertical compartment 332 through the plurality of horizontal slots 336. The processing gases then flows into an exhaust system via the exhaust port 333. In one aspect, the horizontal slots 336 may vary in size depending on the distance between a specific horizontal slot 336 and the exhaust port 333 to provide an even draw across the substrate boat 314 from top to bottom.

It is important to control the temperature of various components in a batch processing chamber especially when a deposition process is to be performed in the batch processing chamber. On the one hand, it is desirable to keep the temperature in the exhaust assembly lower than the temperature in the processing chamber such that the deposition reactions do not occur in the exhaust assembly. On the other hand, it is desirable to heat an exhaust assembly such that processing gases passing the exhaust assembly do not condense and remain on the surface causing particle contamination. Therefore, it is necessary to heat the exhaust assembly independently from the processing volume.

Referring to FIG. 4, cooling channels 334 are formed inside the exhaust assembly 307 to provide control the temperature of the exhaust assembly 307 Horizontal inlet/outlet 335 is connected to the cooling channels 334 such that a heat exchanging fluid may continually flow through the cooling channels 334. The heat exchanging fluid may be, for example, a perfluoropolyether (e.g., Galden® fluid) that is heated to a temperature between about 30° C. and about 300° C. The heat exchanging fluid may also be chilled water delivered at a desired temperature between about 15° C. to 95° C. The heat exchanging fluid may also be a temperature controlled gas, such as, argon or nitrogen.

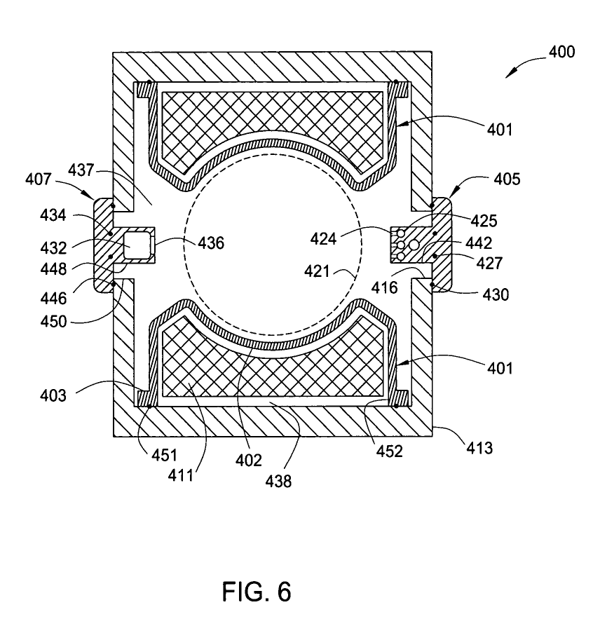

FIG. 6 illustrates a sectional top view of another embodiment of the present invention. A batch chamber 400 generally comprises an outer chamber 413 having two openings 416 and 450 formed opposite to each other. The opening 416 is configured to house an inject assembly 405 and the opening 450 is configured to house an exhaust assembly 407. The outer chamber defines a process volume 437 configured to process a batch of substrates 421 therein. Two quartz containers 401 are generally disposed inside the outer chamber 413. Each of the quartz containers 401 has a curved surface 402 configured to closely hug a portion of a periphery of the substrates 421. Opposing to the curved surface 402 is an opening 452 around which a flange 403 may be formed. The quartz containers 401 are sealingly connected to the outer chamber 413 from inside at the openings 452 such that the quartz containers 401 cut out heater volumes 438 from the process volume 437. Heater blocks 411 are disposed inside the heater volumes 438 such that the substrates 421 may be heated by the heater blocks 411 through the curved surfaces 402 of the quartz containers 401. An O-ring seal 451 may be used to provide vacuum seal between the process volume 437 and the heater volume 438. In one aspect, the heater volumes 438 may be kept in a vacuum state and the heater blocks 411 may be vacuum compatible heaters, such as ceramic resistive heaters. In another aspect, the heater volumes 438 may be kept in atmospheric pressure and the heater blocks 411 are regular resistive heaters. In one embodiment, the heater blocks 411 may be made of several controllable zones such that heating effects may be adjusted by region. In another embodiment, the heater blocks 411 may be removable from a side and/or a top of the outer chamber 413. Examples of removable heaters used in batch processing is further described in U.S. patent application, entitled “Removable Heater”, attorney docket number APPM/009826/FEP/LPCVD/AG, which is incorporated herein by reference.

An O-ring 430 is used to sealingly connect the inject assembly 405 to the outer chamber 413. The inject assembly 405 has an intruding center portion 442 extending into the process volume 437. The inject assembly 405 having one or more vertical inlet tubes 424 formed within the intruding center portion 442. A plurality of horizontal inlet holes 425 are connected to the vertical inlet tubes 424 forming a vertical shower head configured to provide one or more processing gases to the process volume 437. In one aspect, the inject assembly 405 is temperature controlled independently from the process volume 437. Cooling channels 427 are formed inside the inject assembly 405 for circulating of cooling heat exchanging fluids therein. The heat exchanging fluid may be, for example, a perfluoropolyether (e.g., Galden® fluid) that is heated to a temperature between about 30° C. and about 300° C. The heat exchanging fluid may also be chilled water delivered at a desired temperature between about 15° C. to 95° C. The heat exchanging fluid may also be a temperature controlled gas, such as, argon or nitrogen.

An O-ring 446 is used to sealingly connect the exhaust assembly 407 to the outer chamber 413. The exhaust assembly 407 has an intruding center portion 448 extending into the process volume 437. The exhaust assembly 407 having one vertical compartment 432 formed within the intruding center portion 448. A plurality of horizontal slots 436 are connected to the vertical compartment 432 configured to draw processing gases from the process volume 437. In one aspect, the exhaust assembly 407 is temperature controlled independently from the process volume 437. Cooling channels 434 are formed inside the exhaust assembly 407 for circulating of cooling heat exchanging fluids therein. The heat exchanging fluid may be, for example, a perfluoropolyether (e.g., Galden® fluid) that is heated to a temperature between about 30° C. and about 300° C. The heat exchanging fluid may also be chilled water delivered at a desired temperature between about 15° C. to 95° C. The heat exchanging fluid may also be a temperature controlled gas, such as, argon or nitrogen.

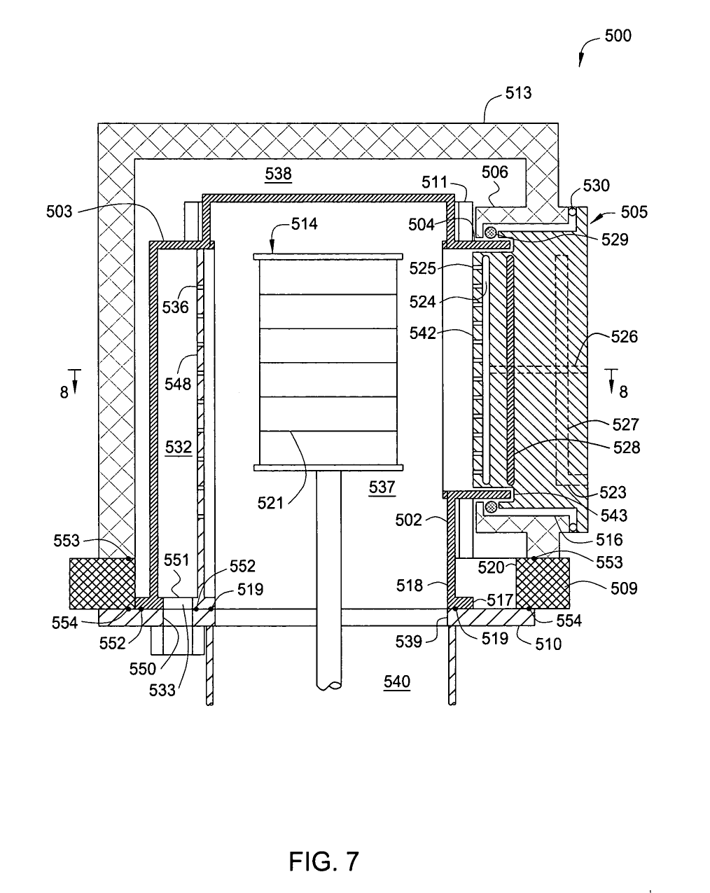

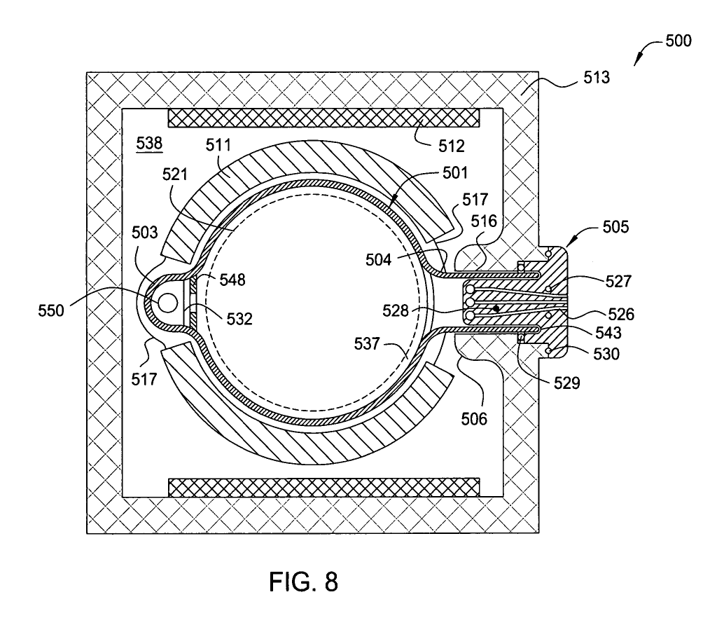

FIGS. 7 and 8 illustrate another embodiment of a batch processing chamber having a quartz chamber with opposing pockets for exhaust and injection. In this embodiment, the exhaust pocket has a bottom port which reduces complexity of a batch processing chamber by eliminating an exhaust assembly and number of O-ring seals required. FIG. 7 is a sectional side view of a batch processing chamber 500 and FIG. 8 is a sectional view of the batch processing chamber 500 along direction 8-8 shown in FIG. 7. The batch processing chamber 500 generally comprises a quartz chamber 501 defining a process volume 537 configured to accommodate a batch of substrates 521 stacked in a substrate boat 514. One or more heater blocks 511 are generally arranged around the quartz chamber 501 configured to heat the substrates 521 inside the process volume 537. An outer chamber 513 is disposed over the quartz chamber 501 and the one or more heater blocks 511. One or more thermal insulators 512 are disposed between the outer chamber 513 and the one or more heater blocks 511 and are configured to keep the outer chamber 513 staying cool. The quartz chamber 501 is supported by a quartz support plate 510. The outer chamber 513 is connected to a chamber stack support 509 which is supported by the quartz support plate 510.

The quartz chamber 501 generally comprises a chamber body 502 having a bottom opening 518, an inject pocket 504 formed on one side of the chamber body 502, an exhaust pocket 503 formed on the chamber body 502 on an opposite side of the inject pocket 504, and a flange 517 formed adjacent to the bottom opening 518. The exhaust pocket 503 and the inject pocket 504 may be welded in place of slots milled on the chamber body 502. The inject pocket 504 has a shape of a flattened quartz tubing with one end welded on the chamber body 502 and one end open. The exhaust pocket 503 has a shape of a partial pipe with its side welded on the chamber body 502. The exhaust pocket 503 has a bottom port 551 and opens at bottom. An exhaust block 548 is disposed between the chamber body 502 and the exhaust pocket 503 and is configured to limit fluid communication between the process volume 537 and an exhaust volume 532 of the exhaust pocket 503. The flange 517 may be welded on around the bottom opening 518 and the bottom port 551 and is configured to facilitate vacuum seal for both the chamber body 502 and the exhaust pocket 503. The flange 517 is generally in intimate contact with the quartz support plate 510 which has apertures 550 and 539. The bottom opening 518 aligns with the aperture 539 and the bottom port 551 aligns with aperture 550. An O-ring seal 519 may be disposed between the flange 517 and the quartz support plate 510 to seal the process volume 537 from an outer volume 538 defined by the outer chamber 513, the chamber stack support 509, the quartz support plate 510 and the quartz chamber 501. An O-ring 552 is disposed around the bottom port 551 to seal the exhaust volume 532 and the outer volume 538. The quartz support plate 510 is further connected to a load lock 540 where the substrate boat 514 may be loaded and unloaded. The substrate boat 514 may be vertically translated between the process volume 537 and the load lock 540 via the aperture 539 and the bottom opening 518.

Referring to FIG. 8, the heater blocks 511 wrap around an outer periphery of the quartz chamber 501 except near the inject pocket 504 and the exhaust pocket 503. The substrates 521 are heated to an appropriate temperature by the heater blocks 511 through the quart chamber 501. In one aspect, edges of the substrates 514 are evenly distanced from the quartz chamber 501 because both the substrates 521 and the chamber body 502 are circular. In another aspect, the heater blocks 511 may have multiple controllable zones so that temperature variations between regions may be adjusted. In one embodiment, the heater blocks 511 may have curved surfaces that partially wrap around the quartz chamber 501.

Referring to FIG. 7, the inject pocket 504 welded on a side of the chamber body 502 defines an inject volume 541 in communication with the process volume 537. The inject volume 541 generally covers an entire height of the substrate boat 514 when the substrate boat 514 is in a process position such that the inject assembly 505 disposed in the inject pocket 504 may provide a horizontal flow of processing gases to every substrate 521 in the substrate boat 514. In one aspect, the inject assembly 505 having an intruding center portion 542 configured to fit in the inject volume 541. A recess 543 configured to hold walls of the inject pocket 504 is generally formed around the center portion 542. The walls of the inject pocket 504 is generally wrapped around by the inject assembly 505. An inject opening 516 is formed on the outer chamber 513 to provide a pathway for the inject assembly 505. A rim 506 extending inward is formed around the inject opening 516 and is configured to shield the inject assembly 505 from being heated by the heater blocks 511. In one aspect, the outer volume 538, which generally includes inside of the outer chamber 513 and outside of the quartz chamber 501, is kept in a vacuum state. Since the process volume 537 and the inject volume 541 are usually kept in a vacuum state during process, keeping the outer volume 538 vacuumed can reduce pressure generated stress on the quartz chamber 501. An O-ring seal 530 is disposed between the inject assembly 505 and the outer chamber 513 to provide a vacuum seal for the inject volume 541. A barrier seal 529 is generally disposed outside the inject pocket 504 preventing processing chemicals in the process volume 537 and the inject volume 541 from escaping to the outer volume 538. In another aspect, the outer volume 338 may be kept in atmospheric pressure.

Referring to FIG. 8, three inlet channels 526 are milled horizontally across the inject assembly 505. Each of the three inlet channels 526 is configured to supply the process volume 537 with a processing gas independently. Each of the inlet channel 526 is connected to a vertical channel 524 formed near an end of the center portion 542. The vertical channels 524 are further connected to a plurality of evenly distributed horizontal holes 525 and form a vertical shower head on the center portion 542 of the inject assembly 505 (shown in FIG. 7). During process, a processing gas first flows from one of the inlet channels 526 to the corresponding vertical channel 524. The processing gas then flows into the process volume 537 horizontally through the plurality of horizontal holes 525. In one embodiment, more or less inlet channels 526 may be formed in the inject assembly 505 depending on requirements of the process performed in the batch processing chamber 500. In another embodiment, since the inject assembly 505 may be installed and removed from outside of the outer chamber 513, the inject assembly 505 may be interchangeable to satisfy different needs.

Referring to FIG. 7, one or more heaters 528 are disposed inside the inject assembly 505 adjacent to the inlet channels 526. The one or more heaters 528 are configured to heat the inject assembly 505 to a set temperature and may be made of resistive heater elements, heat exchangers, etc. Cooling channels 527 are formed in the inject assembly 505 outside the one or more heaters 528. In one aspect, the cooling channels 527 provide further control the temperature of the inject assembly 505. In another aspect, the cooling channels 527 keep an outside surface of the inject assembly 505 staying cool. In one embodiment, the cooling channels 527 may comprise two vertical channels that drilled slightly in an angle so that they meet on one end. Horizontal inlet/outlet 523 is connected to each of the cooling channels 527 such that a heat exchanging fluid may continually flow through the cooling channels 527. The heat exchanging fluid may be, for example, a perfluoropolyether (e.g., Galden® fluid) that is heated to a temperature between about 30° C. and about 300° C. The heat exchanging fluid may also be chilled water delivered at a desired temperature between about 15° C. to 95° C. The heat exchanging fluid may also be a temperature controlled gas, such as, argon or nitrogen.

The exhaust volume 532 is in fluid communication with the process volume 537 via the exhaust block 548. In one aspect, the fluid communication may be enabled by a plurality of slots 536 formed on the exhaust block 548. The exhaust volume 532 is in fluid communication pumping devices through a single exhaust port hole 533 located at the bottom of exhaust pocket 503. Therefore, processing gases in the process volume 537 flow into the exhaust volume 532 through the plurality of slots 536, then go down to the exhaust port hole 533. The slots 536 locate near the exhaust port hole 533 would have a stronger draw than the slots 536 away from the exhaust port hole 533. To generate an even draw from top to bottom, sizes of the plurality of slots 536 may be varied, for example, increasing the size of the slots 536 from bottom to top.

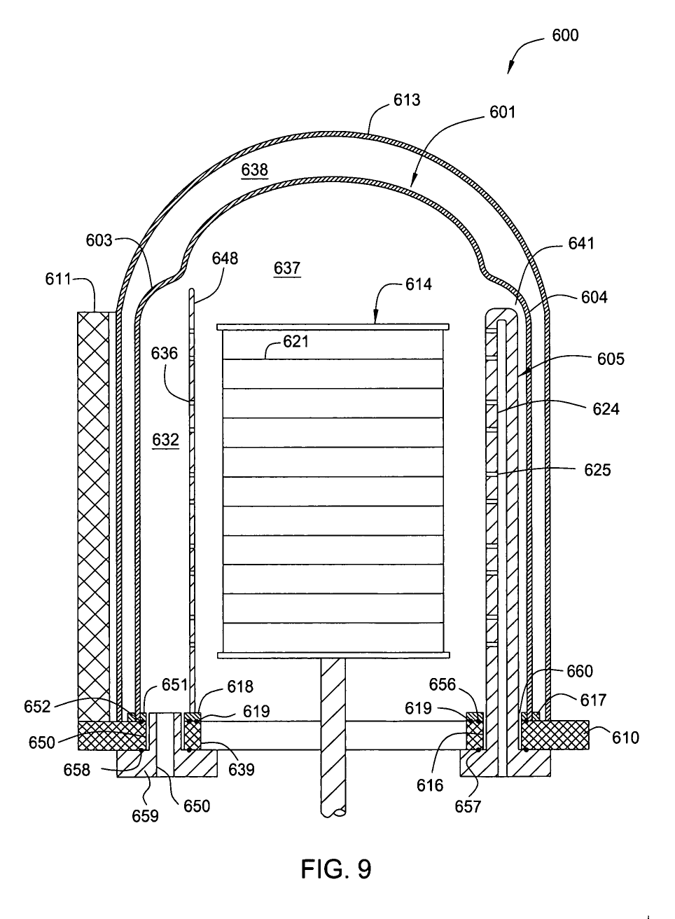

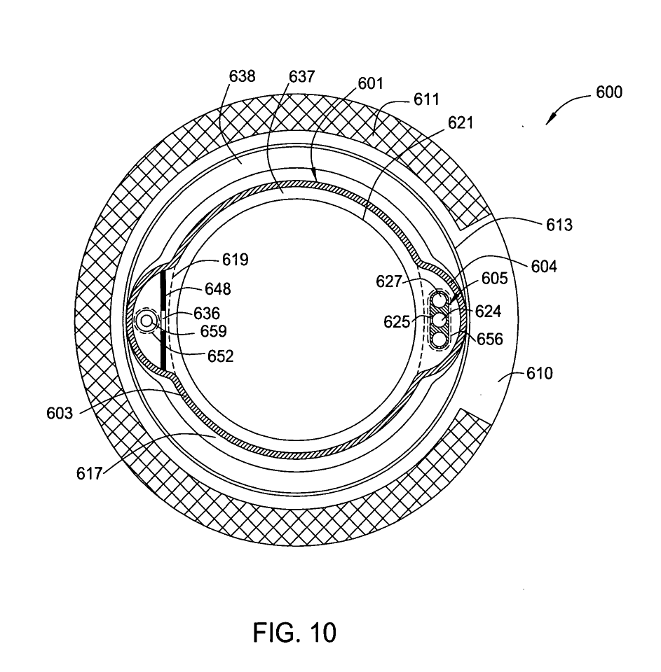

FIGS. 9 and 10 illustrate another embodiment of the present invention. FIG. 9 is a sectional side view of a batch processing chamber 600. FIG. 10 is a sectional top view of the batch processing chamber 600. Referring to FIG. 10, the batch processing chamber 600 comprises a cylindrical outer chamber 613 surrounded by a heater 61 1. A quartz chamber 601 having an exhaust pocket 603 and an inject pocket 604 is disposed inside the outer chamber 613. The quartz chamber 601 defines a process volume 637 configured to house a batch of substrates 621 during process, an exhaust volume 632 inside the exhaust pocket 603, and an inject volume 641 inside the inject pocket 604. In one aspect, the heater 611 may surround the outer chamber 613 for about 280 degrees leaving regions near the inject pocket 604 open.

The outer chamber 613 may be made of suitable high temperature materials such as aluminum, stainless steel, ceramic, and quartz. The quartz chamber 601 may be made of quartz. Referring to FIG. 9, both of the quartz chamber 601 and the outer chamber 613 are open at bottom and are supported by a support plate 610. The heater 611 is also supported by the support plate 610. A flange 617 may be welded on the quartz chamber 601 near the bottom to facilitate vacuum seal between the quartz chamber 601 and the support plate 610. In one aspect, the flange 617 may be a plate with three holes 651, 618 and 660 which are open to the exhaust volume 632, the process volume 637 and the inject volume 641 respectively. Openings 650, 639, and 616 are formed in the support plate 610 and are aligned with the holes 651, 618 and 660 respectively. The flange 617 is in intimate contact with the support plate 610. O-rings 652, 619 and 656 are disposed between the flange 617 and the support plate 610 around the holes 651, 618 and 660 respectively. The O-rings 652, 619 and 656 provide vacuum seal between the process volume 637, the exhaust volume 632 and the inject volume 641 inside the quartz chamber 601 and an outer volume 638 which is inside the outer chamber 613 and outside the quartz chamber 601. In one aspect, the outer volume 638 is kept in a vacuum state to reduce stress on the quartz chamber 601 during process.

An inject assembly 605 configured to supply processing gases is disposed in the inject volume 641. In one aspect, the inject assembly 605 may be inserted and removed through the opening 616 and the hole 660. An O-ring 657 may be used between the support plate and the inject assembly 605 to seal the opening 616 and the hole 660. A vertical channel 624 is formed inside the inject assembly 605 and is configured to flow processing gases from the bottom. A plurality of evenly distributed horizontal holes 625 are drilled in the vertical channel 624 forming a vertical shower head for even disbursement of the gas up and down the process volume 637. In one aspect, multiple vertical channels may be formed in the inject assembly 605 to supply multiple process gases independently. Referring to FIG. 10, since the inject assembly 605 is not immediately surrounded by the heater 611, the inject assembly 605 may be independently temperature controlled. In one aspect, vertical cooling channels 627 may be formed inside the inject assembly 605 providing means to control the temperature of the inject assembly 605.

Referring to FIG. 9, the exhaust volume 632 is in fluid communication with the process volume 637 via an exhaust block 648 disposed the exhaust volume 632. In one aspect, the fluid communication may be enabled by a plurality of slots 636 formed on the exhaust block 648. The exhaust volume 632 is in fluid communication pumping devices through a single exhaust port 659 disposed in the opening 650 near the bottom of the exhaust volume. Therefore, processing gases in the process volume 637 flow into the exhaust volume 632 through the plurality of slots 636, then go down to the exhaust port 659. The slots 636 locate near the exhaust port 659 would have a stronger draw than the slots 636 away from the exhaust port 659. To generate an even draw from top to bottom, sizes of the plurality of slots 636 may be varied, for example, increasing the size of the slots 636 from bottom to top.

The batch processing chamber 600 is advantageous in several ways. Cylindrical jar chambers, 601 and 613, are efficient volume wise. The heater 611 positioned outside both chambers 601 and 613 is easy to maintain. The inject assembly 605 can be independently temperature controlled which is desirable in many processes. The exhaust port 659 and the inject assembly 605 are installed from bottom, which reduces O-ring seals and complexity of maintenance.

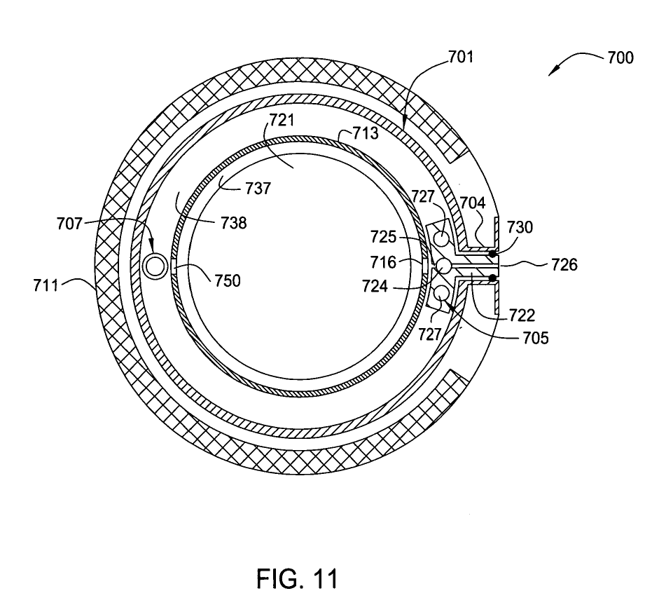

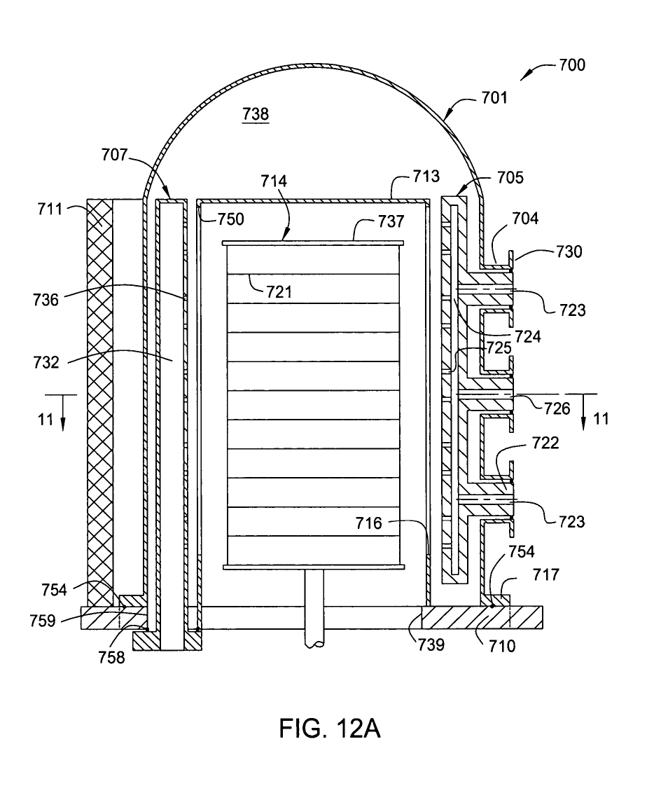

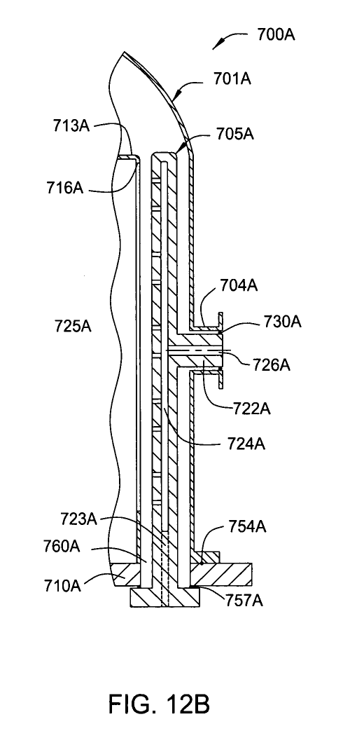

FIGS. 11 and 12A illustrate another embodiment of the present invention. FIG. 12A is a sectional side view of a batch processing chamber 700. FIG. 11 is a sectional top view of the batch processing chamber 600 along direction 11-11 shown in FIG. 12A. Referring to FIG. 11, the batch processing chamber 700 comprises a quartz chamber 701 surrounded by a heater 711. A liner jar 713 is disposed inside the quartz chamber 701. The liner jar 713 defines a process volume 737 which is configured to house a batch of substrates 721 during process. The quartz chamber 701 and the liner jar 713 define an outer volume 738. An exhaust assembly 707 is disposed in the outer volume 738 and an inject assembly 705 is also disposed in the outer volume 738 on an opposite side of the exhaust assembly 707. Two narrow openings 750 and 716 are formed on the liner jar 713 near the exhaust assembly 707 and the inject assembly 705 respectively and are configured to facilitate the exhaust assembly 707 and the inject assembly 705 fluid communication with the process volume 737. In one aspect, the heater 711 may surround the quartz chamber 701 for about 280 degrees leaving regions near the inject assembly 705 open such that the inject assembly 705 may be temperature controlled independently.

Referring to FIG. 12A, both of the quartz chamber 701 and the liner jar 713 are open at bottom and are supported by a support plate 710. In one aspect, the heater 711 is also supported by the support plate 710. The liner jar 713 is cylindrical and is configured to house a substrate boat 714. In one aspect, the liner jar 713 is configured to limit processing gases within the process volume 737 to reduce the amount of processing gases required and to shorten the residence time, which is the average time for a molecule of gas to travel from the point of injections to its being exhausted from the chamber. In another aspect, the liner jar 713 may serve as a thermal diffuser to heat energy emitted from the quartz chamber 701 to improve uniformity of heat distribution among the substrates 721. Further, the liner jar 713 may prevent film deposition on the quartz chamber 701 during process. The liner jar 713 is made of suitable high temperature materials such as aluminum, stainless steel, ceramic, and quartz.

The quartz chamber 701 may have a flange 717 welded on near the bottom. The flange 717 is configured to be in intimate contact with the support plate 710. An O-ring seal 754 may be applied between the flange 717 and the support plate 710 to facilitate a vacuum seal for the quartz chamber 701.

The exhaust assembly 707 has a shape of a pipe with top end closed and a plurality of slots 736 formed on one side. The plurality of slots 736 are facing the opening 750 of the liner jar 713 such that the process volume 737 is in fluid communication with an exhaust volume 732 inside the exhaust assembly 707. The exhaust assembly 707 may be installed from an exhaust port 759 formed on the support plate 710 and an O-ring 758 may be used to seal the exhaust port 750.

The inject assembly 705 is snuggly fit in between the quartz chamber 701 and the liner jar 713. The inject assembly 705 has three input extensions 722 extended outwards and disposed in three inject ports 704 formed on a side of the quartz chamber 701. O-ring seals 730 may be used to seal between the inject ports 704 and the input extensions 722. In one aspect, the inject assembly 705 may be installed by inserting the input extensions 722 into the inject ports 704 from inside of the quartz chamber 701. The inject ports 704 may be welded on sidewall of the quartz chamber 701. In one aspect, the input extensions 722 may be very short such that the inject assembly 705 may be removed from the chamber by dropping down for easy maintenance. Referring to FIG. 11, a vertical channel 724 is formed inside the inject assembly 705 and is configured to be in fluid communication with a horizontal channel 726 formed in input extension 722 in the middle. A plurality of evenly distributed horizontal holes 725 are drilled in the vertical channel 724 forming a vertical shower head. The horizontal holes 725 are directed to the opening 716 of the liner jar 713 such that processing gases flown in from the horizontal channel 726 may be evenly disbursed up and down the process volume 737. In one aspect, multiple vertical channels 724 may be formed in the inject assembly 705 to supply multiple process gases independently. Vertical cooling channels 727 are formed inside the inject assembly 705 providing means to control the temperature of the inject assembly 705. Referring to FIG. 12A, the cooling channels 727 are connected to input channels 723 formed in input extensions 722 at the top and bottom. By providing the processing gases from the input extension 722 located in the middle, the average path of the processing gases is shortened.

FIG. 12B illustrates another embodiment of an inject assembly 705A to be used in an batch processing chamber 700A, which is similar to the batch processing chamber 700. The inject assembly 705A is snuggly fit in between a quartz chamber 701A and a liner jar 713A. The inject assembly 705A has an input extension 722A extended outwards and disposed in an inject port 704 formed on a side of the quartz chamber 701A. An O-ring seal 730A is used to seal between the inject port 704A and the input extension 722A. A vertical channel 724A is formed inside the inject assembly 705A and is configured to be in fluid communication with a horizontal channel 726A formed in the input extension 722A. A plurality of evenly distributed horizontal holes 725A are drilled in the vertical channel 724A forming a vertical shower head. The horizontal holes 725A are directed to an opening 716A of the liner jar 713A such that processing gases flown in from the horizontal channel 726A may be evenly disbursed up and down the liner jar 713A. Vertical cooling channels 727A are formed inside the inject assembly 705A providing means to control the temperature of the inject assembly 705A. The cooling channels 727A are open at the bottom. The inject assembly 705A may be installed from an inject port 760A formed on a support plate 710A and an O-ring 757A may be used to seal the inject port 760A.

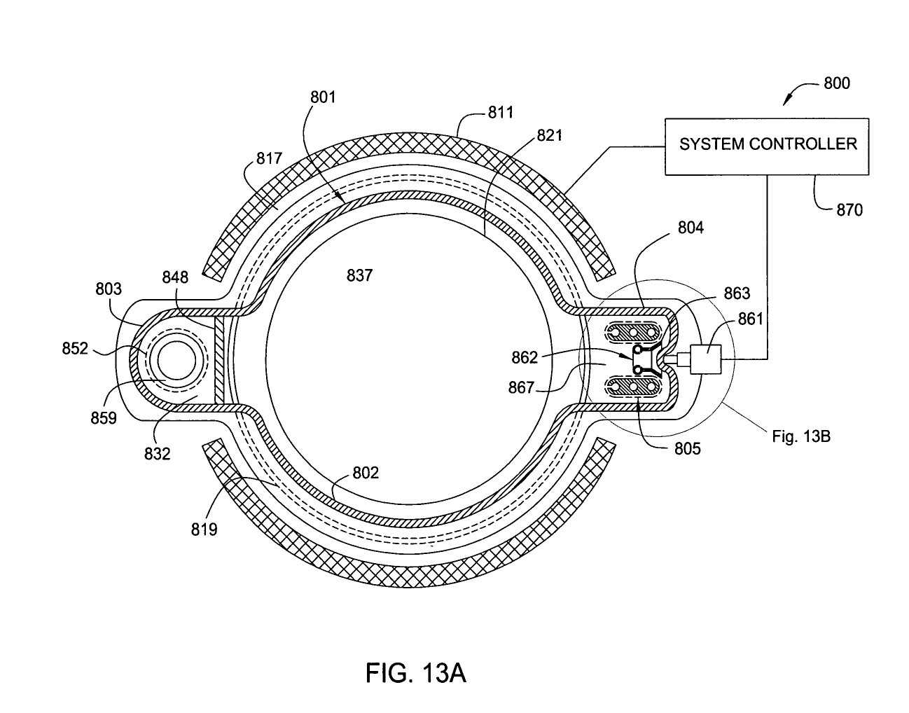

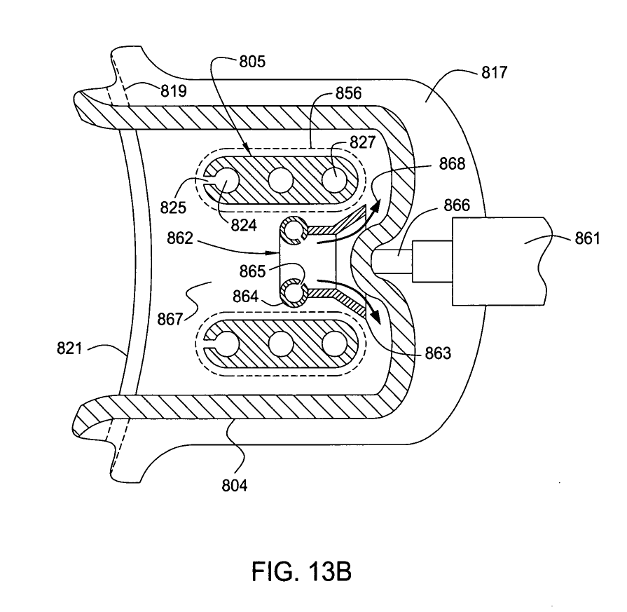

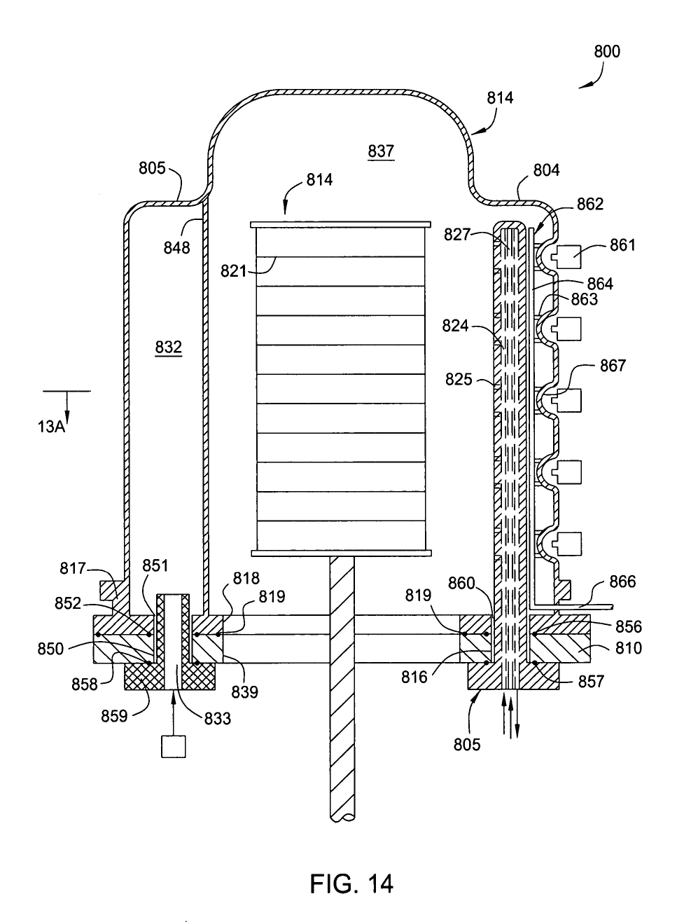

FIGS. 14-16 illustrate another embodiment of a batch processing chamber wherein the chamber temperature can be monitored by sensors positioned outside the chamber. FIG. 14 illustrates a sectional side view of a batch processing chamber 800. FIG. 13A illustrates a sectional top view of the batch processing chamber 800 along directions 13A-13A shown in FIG. 14. FIG. 13B is an exploded view of FIG. 13A.

Referring to FIG. 13A, the batch processing chamber 800 comprises a quartz chamber 801 surrounded by a heater 811. The quartz chamber 801 comprises a cylindrical chamber body 802, an exhaust pocket 803 on one side of the chamber body 802, and an inject pocket 804 opposing the exhaust pocket 803. The chamber body 802 defines a process volume 837 which is configured to accommodate a batch of substrates 821 during process. An exhaust block 848 is disposed between the chamber body 802 and the exhaust pocket 803. An exhaust volume 832 is defined by the exhaust pocket 803 and the exhaust block 848. An exhaust conduit 859 in fluid communication with a pumping device is disposed in the exhaust volume 832. In one aspect, two inject assemblies 805 are disposed in the inject pocket 804. The two inject assemblies 805 are positioned side by side leaving an open corridor 867 between them. In one aspect, each inject assembly 805 may be configured to supply the process volume 837 with processing gases independently. The inject pocket 804 having a plurality of dimples 863 in which a plurality of sensors 861 are disposed. The sensors 861 are configured to measure temperatures of substrates 821 inside the quartz chamber 801 by “looking” into the transparent quartz chamber 801 through the open corridor 867 between the inject assemblies 805. In one aspect, the sensors 861 are optical pyrometers which can determine the temperature of a body by analyzing radiation emitted by the body without any physical contact. The sensors 861 is further connected to a system controller 870. In one aspect, the system controller 870 is able to monitor and analyze temperatures of the substrates 821 being processed. In another aspect, the system controller 870 may send control signals to the heater 811 according to measurements from the sensors 861. In yet another aspect, the heater 811 may comprise several controllable zones such that the system controller 870 is able to control the heater 811 by region and adjust heating characteristics locally.

Referring to FIG. 14, the quartz chamber 801 is open at bottom and has a flange 817 around the bottom. The flange 817 may be welded on and is configured to be in intimate contact with a support plate 810. In one embodiment, both the exhaust pocket 803 and the inject pocket 804 are open at the bottom of the quartz chamber 801. In one aspect, the flange 817 may be a quartz plate having an exhaust opening 851, a center opening 818, and two inject openings 860. The exhaust opening 851 is configured for the exhaust conduit 859 to be inserted into the exhaust pocket 805. The center opening 818 is configured for a substrate boat 814 to transfer the substrates 821 to and from the process volume 837. The inject openings 860 are configured for the inject assemblies 805 to be inserted into the inject pocket 804. Accordingly, the support plate 810 has openings 850, 839, and 816 aligned with the exhaust opening 851, the center opening 818, and the inject openings 860 respectively. O-ring seals 852, 819, and 856 are disposed between the support plate 810 and the flange 817 around the openings 850, 839, and 816. When the exhaust conduit 859 is assembled, a second O-ring 858 is disposed around the opening 850 underneath the support plate 810. This double o-ring sealing configuration allows the exhaust conduit 859 to be removed and serviced without affecting the rest of the batch processing chamber 800. The same sealing configuration may be arranged around the inject assemblies 805. O-rings 857 are disposed around the openings 816 for vacuum sealing of the inject assemblies 805.

The exhaust volume 832 is in fluid communication pumping devices through a single exhaust port hole 833 near the bottom of the exhaust volume 832. The exhaust volume 832 is in fluid communication with the process volume 837 via the exhaust block 848. To generate an even draw from top to bottom of the exhaust volume 832, the exhaust block 848 may be a tapered baffle which narrows from bottom to top.

A vertical channel 824 is formed inside the inject assembly 805 and is configured to be in fluid communication with sources of processing gases. A plurality of evenly distributed horizontal holes 825 are drilled in the vertical channel 824 forming a vertical shower head. The horizontal holes 825 are directed to the process volume 837 such that processing gases flown in from the vertical channel 824 may be evenly disbursed up and down the process volume 837. Vertical cooling channels 827 are formed inside the inject assembly 805 providing means to control the temperature of the inject assembly 805. In one aspect, two of the vertical cooling channels 827 may be milled from the bottom of the inject assembly 805 in a small angle such that they meet at the top. Therefore, a heat exchanging fluid may be flown in from one of the cooling channels 827 and flown out from the other cooling channel 827. In one aspect, the two inject assemblies 805 may be temperature controlled independently from one another according to the process requirement.

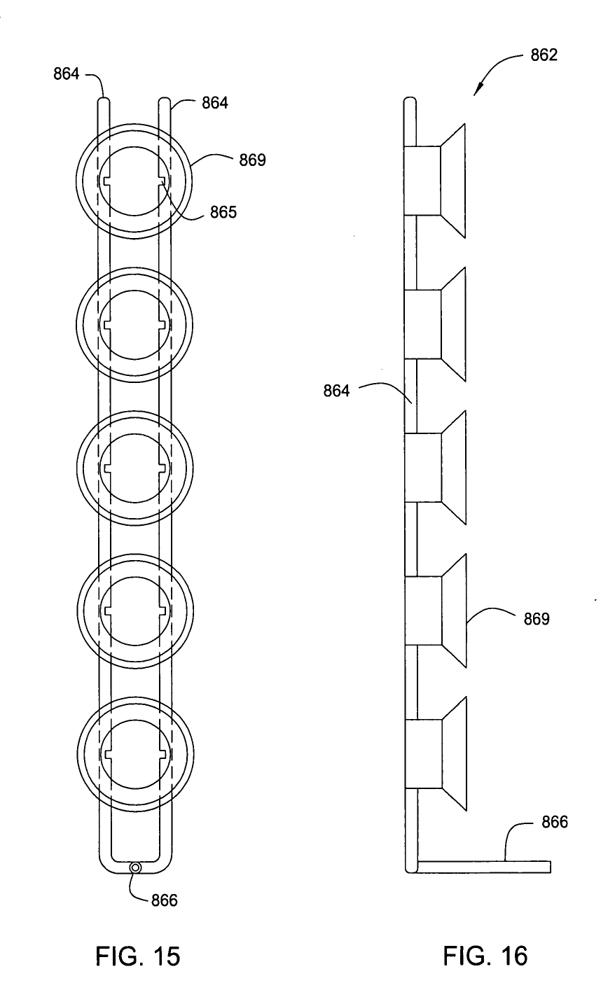

During some processes, especially deposition processes, the chemical gases used in the process may deposit and/or condense on the quartz chamber 801. Deposition and condensation near the dimples 863 can blur “visions” of the sensors 861 and reduce accuracy of the sensors 861. Referring to FIG. 13B, a cleaning assembly 862 is positioned inside the inject pocket 804. The cleaning assembly 862 blows a purge gas to inner surfaces of the dimples 863 so that areas near the dimples 863 are not exposed to the chemical gases used in the process. Therefore, keep undesired deposition and condensation from happening. FIGS. 15 and 16 illustrate one embodiment of the cleaning assembly 862. FIG. 15 is a front view of the cleaning assembly 862 and FIG. 16 is a side view. An inlet tube 866 configured to receive a purge gas from a purge gas source is connected to a tube fork 864 having a plurality of holes 865 corresponding to the dimples 863 shown in FIGS. 13A, 13B and 14. A plurality of cups 869 are attached to the tube fork 864. During process, a purge gas flows in the tube fork 864 through the inlet tube 866 and flows out the tube fork 864 through the plurality of holes 865. Referring to FIG. 13B, the cups 869 loosely cover the corresponding dimples 863 and are configured to direct the purge gas to flow along directions 868.

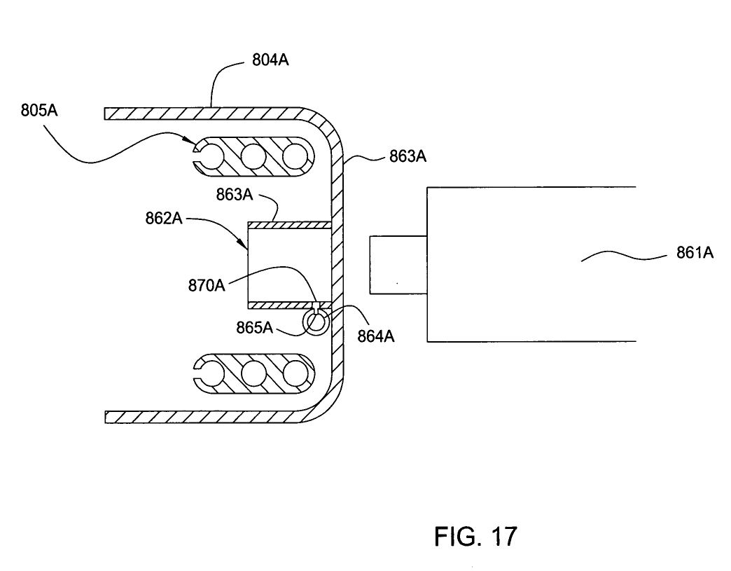

FIG. 17 illustrates another embodiment of an inject pocket 804A having two inject assemblies 805A and observing windows 863A for temperature sensors 861A. Quartz tubes 862A is welded on a sidewall of the inject pocket 804A. The observing windows 863A are defined by the areas inside the quartz tubes 862A. Each of the quartz tubes 862A has an slot 870A near which a purge gas supplying tube 864A is positioned. The purge gas supplying tube 864A has a plurality of holes 865A directed to the corresponding slots 870A of the quartz tubes 862A. A purge gas may flow from the purge gas supplying tube 864A to the observing windows 863A through the holes 865A and the slots 870A. This configuration simplifies the inject pocket 804A by omitting the dimples 863 shown in FIG. 13B.

While the foregoing is directed to embodiments of the present invention, other and further embodiments of the invention may be devised without departing from the basic scope thereof, and the scope thereof is determined by the claims that follow.

1. A batch processing chamber comprising:
a quartz chamber configured to process a batch of substrates therein;
at least one heater block disposed outside the quartz chamber;
an inject assembly attached to the quartz chamber; and
an exhaust assembly attached to the quartz jar on an opposite side of the inject assembly.

2. The batch processing chamber of claim 1, further comprising an outer chamber configured to enclose the quartz chamber and the at least one heater block.

3. The batch processing chamber of claim 2 further comprising at least one thermal insulator disposed between the at least one heater block and the outer chamber.

4. The batch processing chamber of claim 2 further comprising an inject thermal insulator disposed between the inject assembly and the outer chamber.

5. The batch processing chamber of claim 2 further comprising an exhaust thermal insulator disposed between the exhaust assembly and the outer chamber.

6. The batch processing chamber of claim 1, further comprising a liner jar disposed inside the quartz chamber, wherein the liner jar is configured to accommodate the batch of substrates, wherein the inject assembly and the exhaust assembly are disposed between the quartz chamber and the liner jar.

7. The batch processing chamber of claim 6, wherein the quartz chamber comprises an inject port configured to provide processing gases to the inject assembly.

8. The batch processing chamber of claim 6, wherein the quartz chamber comprises:
an inject port configured to provide processing gases to the inject assembly; and
two cooling ports configured to provide heat exchanging fluids to the inject assembly,
wherein the inject port is positioned near a middle level of the quartz chamber.

9. The batch processing chamber of claim 1, further comprising a cylindrical jar disposed between the at least one heater block and the quartz chamber.

10. The batch processing chamber of claim 1, wherein the quartz chamber comprises an inject pocket connected to the inject assembly and an exhaust pocket connected to the exhaust assembly.

11. The batch processing chamber of claim 10, wherein the inject pocket opens on a side of the quartz chamber and the exhaust pocket opens on an opposite side of the quartz chamber.

12. The batch processing chamber of claim 10, wherein the inject pocket opens on a side of the quartz chamber and the exhaust pocket opens on a bottom of the quartz chamber.

13. The batch processing chamber of claim 10, wherein the exhaust pocket opens on a bottom of the quartz chamber and an exhaust block having a plurality of holes is disposed in the exhaust pocket.

14. The batch processing chamber of claim 13, wherein a tapered baffle is disposed on the exhaust block.

15. The batch processing chamber of claim 10, wherein both the inject pocket and the exhaust pocket open on a bottom of the quartz chamber.

16. The batch processing chamber of claim 1, wherein the inject assembly comprises a vertical shower head configured to dispense at least one processing gas to the quartz chamber.

17. The batch processing chamber of claim 1, wherein the inject assembly comprises cooling channels configured to circulate a heat exchanging fluid.

18. The batch processing chamber of claim 17, wherein the inject assembly further comprises a heater.

19. The batch processing chamber of claim 17, wherein the inject assembly is insulated from the at least one heater block by an inject thermal insulator.

20. The batch processing chamber of claim 1, wherein the exhaust assembly comprises cooling channels configured to circulate a heat exchanging fluid.

21. The batch processing chamber of claim 20, wherein the exhaust assembly is insulated from the at least one heater block by an exhaust thermal insulator.

22. The batch processing chamber of claim 1, wherein the at least one heater block has multiple controllable zones.

23. The batch processing chamber of claim 1, wherein the at least one heater block has vertical zones, each of which is independently controllable.

24. The batch processing chamber of claim 1, further comprising a quartz support plate in contact with the quartz chamber.

25. The batch processing chamber of claim 24, wherein the quartz chamber comprises a flange which is in intimate contact with the quartz support plate.

26. The batch processing chamber of claim 1, further comprising at least one temperature sensor disposed outside the quartz chamber.

27. The batch processing chamber of claim 26, wherein the at least one temperature sensor is an optical pyrometer.

28. The batch processing chamber of claim 26, further comprising a cleaning assembly disposed inside the quartz chamber, wherein the cleaning assembly is configured to blow a purge gas to an inside surface of the quartz chamber corresponding to the at least one temperature sensor.

29. A quartz jar for a batch processing chamber, comprising:
a cylindrical body with an open bottom;
an inject pocket formed on one side of the cylindrical body; and
an exhaust pocket formed on an opposite side to the inject pocket.

30. The quartz jar of 29, wherein the inject pocket is welded on and is open to a side.

31. The quartz jar of 30, wherein the exhaust pocket is welded on and is open a side.

32. The quartz jar of 29, wherein the inject pocket and the exhaust pocket are open to the bottom.

33. The quartz jar of claim 32, wherein the inject pocket contains multiple dimples.

34. The quartz jar of claim 29, further comprising an exhaust block between the quartz body and the exhaust pocket.

35. The quartz jar of claim 29, further comprising a flange welded on near the open bottom.

36. A method for processing a batch of substrates, the method comprising:
delivering a processing gas through an inject assembly having a first controlled temperature; and
injecting the processing gas into a process volume having a second controlled temperature.

37. The method of claim 36, wherein the first controlled temperature is obtained by flowing a heat exchanging fluid in a cooling channel formed in the inject assembly.

38. The method of claim 36, wherein the second controlled temperature is obtained by at least one heater block disposed outside the processing volume.

39. The method of claim 36, further comprising pumping the processing gas out of the process volume through an exhaust assembly having a third controlled temperature.

40. The method of claim 39, wherein the second controlled temperature is obtained by flowing a heat exchanging fluid in a cooling channel formed in the exhaust assembly.

41. A method for monitoring temperature in a process volume defined by a quartz chamber, the method comprising:
heating the process volume using at least one heater block disposed outside the quartz chamber; and
measuring a temperature inside the process volume using at least one pyrometer disposed outside the quartz chamber.

42. The method of claim 41, further comprising adjusting the at least one heater block according the temperature measured by the at least one pyrometer.

43. The method of claim 41, further comprising flowing a purge gas toward an inside surface of the quartz chamber adjacent to the at least one pyrometer.

44. The method of claim 43, further comprising directing the purge gas using at least one quartz cup welded on the inside surface of the quartz chamber.

45. The method of claim 43, further comprising directing the purge gas using at least one quartz tube welded on the inside surface of the quartz chamber.

46. The method of claim 41, further comprising positioning the at least one pyrometer near at least one dimple formed in an inject pocket of the quartz chamber.
